(19) United States
(12) Patent Application Publication
(10) Pub. No.: US 2014/0053903 A1
(43) Pub. Date: Feb. 27, 2014

(54) PHOTOELECTRIC CONVERSION ELEMENT AND SOLAR CELL

(71) Applicant: KABUSHIKI KAISHA TOSHIBA, Tokyo (JP)

(72) Inventors: Naoyuki Nakagawa, Tokyo (JP); Soichiro Shibasaki, Tokyo (JP); Mutsuki Yamazaki, Kanagawa (JP); Shinya Sakurada, Tokyo (JP); Michihiko Inaba, Kanagawa (JP)

(73) Assignee: KABUSHIKI KAISHA TOSHIBA, Tokyo (JP)

(21) Appl. No.: 14/069,531

(22) Filed: Nov. 1, 2013

Related U.S. Application Data
(63) Continuation of application No. PCT/JP2012/061110, filed on Apr. 25, 2012.

(30) Foreign Application Priority Data
May 6, 2011 (JP) 2011-103722

(51) Int. Cl. H01L 31/0336

(52) U.S. Cl. CPC H01L 31/0336
USPC 136/262; 136/264

(57) ABSTRACT

A photoelectric conversion element of an embodiment includes: a light absorbing layer containing copper (Cu), at least one Group IIIb element selected from the group including aluminum (Al), indium (In) and gallium (Ga), and sulfur (S) or selenium (Se), and having a chalcopyrite structure; and a buffer layer formed from zinc (Zn) and oxygen (O) or sulfur (S), wherein the molar ratio represented by S/(S+O) of the buffer layer is equal to or greater than 0.7 and equal to or less than 1.0, and the crystal grain size is equal to or greater than 10 nm and equal to or less than 100 nm.

### CROSS-REFERENCE TO RELATED APPLICATION

This application is a continuation application based upon and claims the benefit of priority from Japanese Patent Applications No. 2011-103722, filed on May 6, 2011; and International Application PCT/JP2012/061110, the International Filing Date of which is Apr. 25, 2012 the entire contents of which are incorporated herein by reference.

### FIELD

Embodiments described herein relate generally to a photoelectric conversion element and a solar cell.

### BACKGROUND

In regard to solar cells for example, the development of compound-based thin film photoelectric conversion elements that use semiconductor thin films as light absorbing layers has been in progress. Attention is being paid to photoelectric conversion elements for thin film solar cells and the like, which use, among those compound semiconductors composed of the elements of Group Ib, Group IIIb and Group VIb and having a chalcopyrite structure, Cu(In, Ga) Se₂ formed from copper (Cu), indium (In), gallium (Ga) and selenium (Se), which is so-called CIGS, in the light absorbing layer. Since CIGS thin film solar cells are heterojunction solar cells in which the p-type compound semiconductor layer (light absorbing layer) and the n-type compound semiconductor layer (buffer layer) are respectively composed of different material systems, their heterojunction interface greatly affects the solar cell characteristics. In the present situation, in the CIGS thin film solar cells that exhibit high conversion efficiency, cadmium sulfide (CdS) is used in the n-type compound semiconductor layer. Advantages of CdS include the conversion of the CIGS surface into n-type due to the diffusion of cadmium (Cd), lattice matching with CIGS, matching of the conduction band offset (CBO), and the like. The conversion efficiency, η, of the photoelectric conversion element is represented by the equation: η=Voc·Jsc·FF/P·100, using the open circuit voltage Voc, the short circuit current density Jsc, the Fill factor FF, and the incident power density P. The conversion efficiency can be increased by increasing Voc or Jsc.

For example, an electrically satisfactory heterojunction interface is formed between CuIn_{0.7}Ga_{0.3}Se₂ and CdS. However, in order to promote matching with the sunlight spectrum, it is necessary to increase the band gap of the CIGS light absorbing layer by about 1.4 eV, and to increase the amount of Ga by up to 70%. However, when CIGS having a high Ga concentration is used, it is difficult to have the CBO matched with CdS, and a high conversion efficiency such as expected is not obtained. Furthermore, since there is a risk that CdS may have adverse effects on the human body, there is a demand for a substitute material.

### BRIEF DESCRIPTION OF THE DRAWINGS

FIG. 1 is a conceptual diagram of a photoelectric conversion element according to embodiments.

FIG. 2A is a conceptual diagram of the energy band diagram of the p-n junction interface in the case where ΔE_{c} of the photoelectric conversion element of the embodiment is larger than zero.

FIG. 2B is a conceptual diagram of the energy band diagram of the p-n junction interface in the case where ΔE_{c} of the photoelectric conversion element of the embodiment is smaller than zero.

FIG. 3 is a schematic diagram of the band structure for the composition of the embodiment.

### DETAILED DESCRIPTION

A photoelectric conversion element of an embodiment includes a light absorbing layer containing copper (Cu), at least one Group IIIb element selected from the group including aluminum (Al), indium (In) and gallium (Ga), and sulfur (S) or selenium (Se), and having a chalcopyrite structure; and a buffer layer formed from zinc (Zn) and oxygen (O) or sulfur (S), wherein the molar ratio represented by S/(S+O) of the buffer layer is equal to or greater than 0.7 and equal to or less than 1.0, and the crystal grain size is equal to or greater than 10 nm and equal to or less than 100 nm.

Embodiments of the invention will be described below with reference to the drawings.

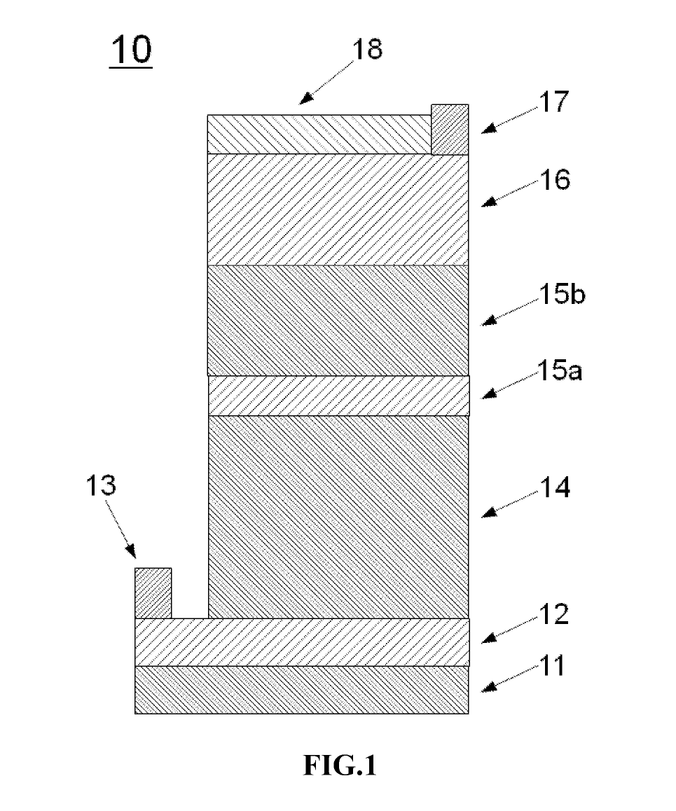

The photoelectric conversion element 10 illustrated in the conceptual diagram of FIG. 1 includes at least a substrate 11; a backside electrode 12 provided on the substrate; a first extraction electrode 13 provided on the backside electrode 12; a light absorbing layer 14 provided on the backside electrode 12; a buffer layer 15 (15a and 15b) provided on the light absorbing layer 14; a transparent electrode layer 16 provided on the buffer layer 15; a second extraction electrode 17 provided on the transparent electrode layer 16; and an antireflective film 18 provided on the transparent electrode layer 16.

The light absorbing layer 14 of the embodiment is preferably a compound semiconductor layer (light absorbing layer) containing Cu, at least one Group IIIb element selected from the group consisting of Al, In and Ga, and S or Se, and having a chalcopyrite structure. Among the Group IIIb elements, it is more desirable to use In because the size of the band gap can be easily brought to an intended value by means of a combination with Ga. Specifically, Cu(In,Ga)Se₂, Cu(In,Ga)₃Se₅, Cu(Al,Ga,In)Se₂ or the like (hereinafter, referred to as CIGS) can be used for the light absorbing layer 14.

It is more preferable that the molar ratio of Ga/Group IIIb elements in the light absorbing layer 14 be equal to or greater than 0.5 and equal to or less than 1.0.

Furthermore, the buffer layer 15a is preferably single phase. In the buffer layer 15a, a compound formed from Zn and O or S is used, a compound having a property as an n-type semiconductor, and specifically, a compound represented by the formula ZnO₁₋ₓSₓ that will be described below can be used.

Here, the buffer layer 15a is preferably such that the molar ratio represented by S/(S+O) in the area in the buffer layer extending up to 10 nm from the interface between the light absorbing layer and the buffer layer, be equal to or greater than 0.7 and equal to or less than 1.0. If this molar ratio is smaller than 0.7, separation into two phases may occur in the buffer layer 15a.

A p-n junction interface is formed by a heterojunction between the light absorbing layer 14 and the buffer layer 15a. However, the surface of the light absorbing layer 14 is converted to n-type by the formation of an ordered vacancy chalcopyrite (OVC; Ordered Vacancy Compound or Ordered Vacancy Chalcopyrite) caused by the diffusion of a portion of Zn, which is a constituent element of the buffer layer 15a, into the light absorbing layer 14 or Cu deficiency at the surface of the light absorbing layer 14, and thereby a p-n junction interface may be formed in the inside of the light absorbing layer 14.

Meanwhile, in the embodiment, the chalcopyrite structure and the ordered vacancy chalcopyrite structure are both described as chalcopyrite structure, except for those occasions in which each of the structures is described separately.

According to the embodiment, it has been said that the crystal grain size of the buffer layer 15a is preferably equal to or greater than 10 nm and equal to or less than 100 nm. This is not preferable because if the crystal grain size is smaller than 10 nm, the p-n junction interface defects and the crystal grain boundaries in the film increase in number, the mobility of photogenerated carriers decreases, and the short circuit current density Jsc is decreased. On the other hand, if the crystal grain size is larger than 100 nm, voids are likely to occur at the p-n junction interface, and the area that can contribute to the p-n junction decreases. Furthermore, when the crystal grain size increases, the film thickness of the n-type buffer layer 15a becomes uneven, and therefore, a shunt path is likely to be produced. All of these cause a decrease in the short circuit current density Jsc, and thus it is not preferable. Furthermore, when the crystal grain size exceeds 100 nm, and voids occur at the p-n junction interface, the peeling resistance at the p-n junction interface decreases. Therefore, the crystal grain size of a ZnO₁₋ₓSₓ film, which serves as the n-type compound semiconductor layer, is preferably equal to or greater than 10 nm and equal to or less than 100 nm. More preferably, the crystal grain size is equal to or greater than 50 nm and equal to or less than 100 nm.

An observation of buffer layer 15 is carried out by chipping the stacked films on top of the buffer layer 15a through ion milling of the central area of the photoelectric conversion element 10. The crystal grain size of the ZnO₁₋ₓSₓ film is a five-point average value at the same depth in the film thickness direction of a cross-sectional Transmission Electron Microscope (TEM) image at a magnification of 500,000 times. Meanwhile, the cross-sectional TEM image is to include the center of the surface of the light absorbing layer 14. The five-point determination method is performed such that a cross-sectional TEM image at a magnification of 500,000 times is equally divided into 5 sections in the thickness direction and the perpendicular direction, and the measurement is made at the centers of the divided areas. When the area of crystals including the center points in the cross-sectional TEM image is designated as S, the crystal grain size of the ZnO₁₋ₓSₓ film is defined as the average value of R as defined by the formula (Equation 1) at the five points:

$$R = 2 \sqrt{\frac{S}{π}} \qquad ( Equation 1 )$$

The conduction band offset (CBO) at the p-n junction interface will be described.

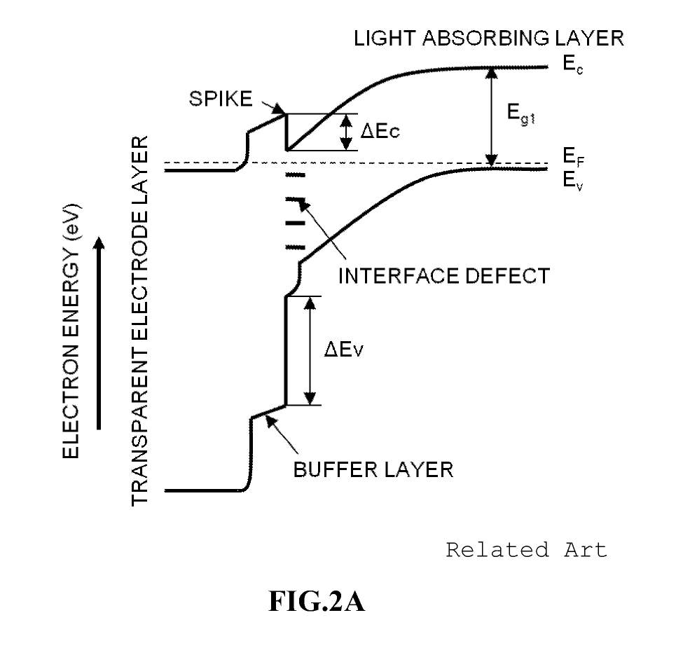

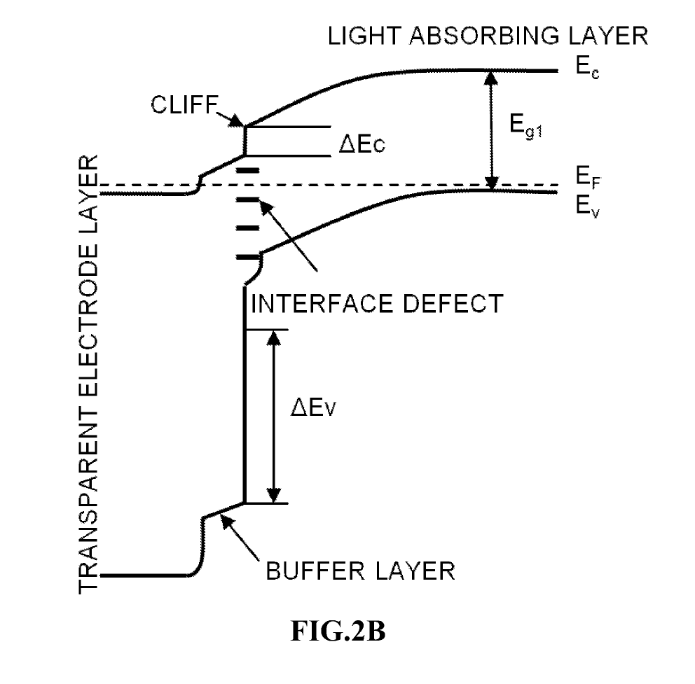

When the p-n junction of a photoelectric conversion element 10 is irradiated with light, electron-hole pairs are generated, and electrons that have been excited to the conduction band are accelerated by the electric field in the depletion layer and move to the transparent electrode 16 through the buffer layer 14. When the position of CBM of the light absorbing layer 14 is designated as E_{cp} (eV), and the position of CBM of the buffer layer 15a is designated as E_{cn} (eV), if the difference in the position of the conduction band minimum (CBM) between the p-type layer and the n-type layer, ΔE_{c} (CBO) (=E_{cn}−E_{cp}), is such as in the case of FIG. 2A at ΔE_{c}>0 eV, this case is called a spike. When the amount of this discontinuity increases, the discontinuity becomes a barrier to photogenerated electrons, so that the photogenerated electrons recombine with holes in the valence band through the interface defects, and cannot reach the transparent electrode 16. On the other hand, at ΔE_{c}<0 eV, the case in which ΔE_{c} sinks as in the case of FIG. 2B, this case is called a cliff. Since photogenerated electrons do not meet a barrier, the photogenerated electrons flows to the transparent electrode 16 regardless of the size of the cliff. However, at this time, the curvature of the depletion layer becomes mild, and the recombination of holes and the electrons injected from the transparent electrode 16 side in the vicinity of the interface increases. As a result, in the case of the cliff, leak current increases, and the open circuit voltage Voc decreases. That is, at the p-n junction interface of the buffer layer 15a and the light absorbing layer 14, it is preferable that there be no discontinuity in the conduction band (ΔE_{c}=0), or the discontinuity of the conduction band form a spike (ΔE_{c}>0), and it is desirable that the amount of discontinuity (ΔE_{c}) forms a height to an extent that does not becomes a barrier to the photogenerated electrons (ΔE_{c}≦0.4 eV). Therefore, the difference of the position of the conduction band minimum, ΔE_{c}, is preferably such that 0≦ΔE_{c}≦0.4.

The position of the CBM can be estimated using the following techniques. The valence band maximum (VBM) is actually measured by photoelectric spectroscopy, which is a method for evaluating the electron occupancy level, and subsequently the CBM is calculated assuming a band gap that is already known. However, at an actual p-n junction interface, an ideal interface is not retained due to mutual diffusion, the occurrence of cation vacancies or the like, and therefore, there is a high possibility that the band gap may change. For this reason, it is preferable that the CBM be also directly evaluated by inverse photoelectron spectroscopy utilizing the reverse process of photoelectron emission. Specifically, the electron state of the p-n junction interface can be evaluated by repeatedly subjecting the surface of a photoelectron conversion element to low energy ion etching and to forward/inverse photoelectron spectroscopy.

Next, the positional relation of the bands of CIGS and ZnO₁₋ₓSₓ as the buffer layer 15a will be described.

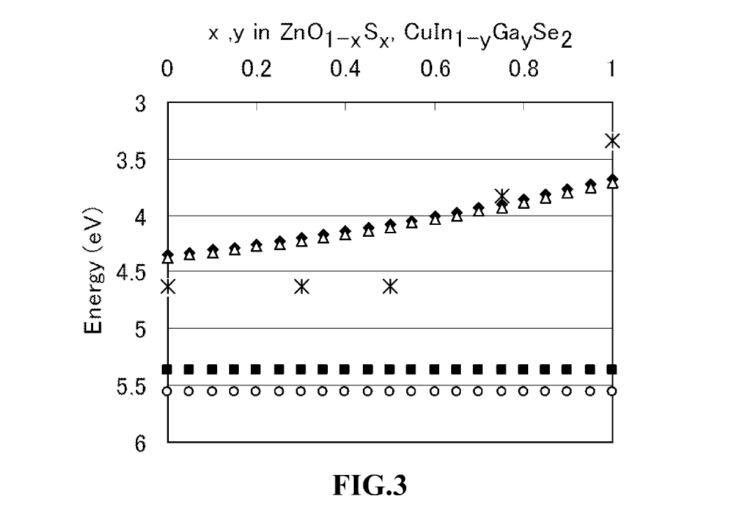

FIG. 3 is a diagram illustrating a summary of the CBM (*) of ZnO₁₋ₓSₓ in the case of changing x between 0 and 1; the CBM (♦:black rhombus) of CuIn_{1-y}Ga_{y}Se₂ as a CIGS in the case of changing y between 0 and 1; the VBM (▪:black square) of CuIn_{1-y}Ga_{y}Se₂ and the CBM (Δ:white triangle) of Cu(In_{1-y}Ga_{y})₃Se₅ in the case of changing y between 0 and 1; and the VBM (◯:white circle) of Cu(In_{1-y}Ga_{y})₃Se₅ in the case of changing y between 0 and 1. As illustrated in FIG. 3, CuIn_{1-y}Ga_{y}Se₂ is such that when y increases (increase in the Ga concentration), the VBM does not change, and only the CBM increases monotonously. On the other hand, ZnO₁₋ₓSₓ is such that when x increases (increase in the S concentration), the CBM almost does not change until x=0.5, and when the S concentration further increases, the CBM rapidly increases (at this time, the VBM increases at 0≦x≦0.5, and almost does not change at 0.5≦x≦1.0). Therefore, when a p-n junction is formed with CIGS at y=0 and ZnO₁₋ₓSₓ at x=0.7, ΔEc is equal to +0.4 eV. With CIGS at y=1.0, a ΔEc of +0.4 eV is obtained by the formation of a p-n junction with ZnO₁₋ₓSₓ at x=1.0. That is, as the n-type buffer layer, ZnO₁₋ₓSₓ (0.7≦x≦1.0) is preferred.

Furthermore, a portion of Se may be substituted with S, and a portion of In and Ga may be substituted with Al, so as to satisfy the relation: 0≦ΔE_{c}≦0.4.

When the CIGS at the surface of the light absorbing layer 14 is in the form of OVC, the VBM decreases by about 0.2 eV, but the CBM almost does not change. Therefore, even in this case, ZnO₁₋ₓSₓ (0.7≦x≦1.0) can be used.

The composition of ZnO₁₋ₓSₓ of the buffer layer 15a is measured by energy dispersive X-ray spectroscopy (EDX) after a calibration by measuring a sample with a known composition. The EDX measurement is carried out by chipping the stacked films on top of the buffer layer 15a through ion milling of the central area of the photoelectric conversion element 10, and making a TEM observation of the cross-section at a magnification of 500,000 times, while at the same time, examining the composition from the average composition obtained at five points. Meanwhile, the five-point determination method is performed such that a cross-sectional TEM image at a magnification of 500,000 times is equally divided into 5 sections in the thickness direction and the perpendicular direction, and the measurement is made at the centers of the divided areas. Meanwhile, the cross-sectional TEM image is to include the center point of the photoelectric conversion element 10.

A position at which the constituent component of the light absorbing layer 14 that is in contact with ZnO₁₋ₓSₓ of the buffer layer 15a, is defined as the p-n junction interface, and it is preferable that at least at the p-n junction interface, ZnO₁₋ₓSₓ that constitutes the buffer layer 15a has a desired composition ratio. Furthermore, it is more preferable that ZnO₁₋ₓSₓ of the n-type buffer layer 15a has a desired composition ratio over the entire region.

In regard to the CIGS that constitutes the light absorbing layer 14, it is desirable that the band gap be adjusted to about 1.4 eV in order to promote matching with the sunlight spectrum. From FIG. 3, when the element ratio Ga/(In +Ga) is adjusted to equal to or greater than 0.5 and equal to or less than 1.0, it is preferable because the band gap becomes equal to or greater than 1.28 eV and equal to or less than 1.68 eV; when the element ratio Ga/(In +Ga) is adjusted to equal to or greater than 0.6 and equal to or less than 0.9, it is more preferable because the band gap becomes equal to or greater than 1.35 eV and equal to or less than 1.59 eV; and when the element ratio Ga/(In +Ga) is adjusted to equal to or greater than 0.65 and equal to or less than 0.85, it is even more preferable because the band gap becomes equal to or greater than 1.39 eV and equal to or less than 1.55 eV.

Meanwhile, it is preferable that the n-type buffer layer 15a of the embodiment be in a single phase. If the n-type buffer layer 15a of the embodiment is in two phases, the band gap of the n-type buffer layer 15a is not unambiguously defined, and the power generation efficiency is decreased, which is not preferable. The phase of the buffer layer 15a can be determined from the number of peaks in XRD.

Hereinafter, the configuration other than the light absorbing layer 14 and the n-type buffer layer 15 used in the photoelectric conversion element will be described.

As the substrate 11, it is desirable to use soda lime glass, and a metal plate of stainless steel, Ti, Cr or the like, or a resin plate of a polyimide or the like can also be used.

As the backside electrode 12, an electrically conductive metal film formed of molybdenum (Mo), tungsten (W) or the like can be used. Among them, it is desirable to use a Mo film.

As the extraction electrodes 13 and 17, for example, an electrically conductive metal such as Al, silver (Ag) or gold (Au) can be used. Furthermore, in order to enhance the adhesiveness to the transparent electrode 15, nickel (Ni) or chromium (Cr) may be deposited, and then Al, Ag or Au may be deposited thereon.

The buffer layer 15b can be considered to function as an n⁺ type layer, and it is desirable to use, for example, ZnO.

The transparent electrode layer 16 needs to be able to transmit sunlight and also to have electrical conductivity. For example, ZnO:Al containing 2 wt % of alumina (Al₂O₃), or ZnO:B obtained by doping B from diborane can be used.

As the antireflective film 18, it is desirable to use, for example, MgF₂.

As the method for producing the photoelectric conversion element 10 of FIG. 1, the following method may be mentioned as an example.

Meanwhile, the production method described below is only an example, and the method may be appropriately changed. Therefore, the order of steps may be modified, or plural steps may also be carried out in combination.

[Process of Forming Backside Electrode on Substrate]

A backside electrode 12 is formed on a substrate 11. As the film-forming method, for example, a thin film forming method such as a sputtering method using a sputter target formed of a conductive metal may be used.

[Process of Forming Light Absorbing Layer on Backside Electrode]

After the backside electrode 12 is deposited, a compound semiconductor thin film that will constitute a light absorbing layer 14 is deposited. Meanwhile, since a light absorbing layer 14 and a first extraction electrode 13 are deposited on the backside electrode 12, a light absorbing layer 14 is deposited on a portion of the backside electrode 12 excluding at least the area where the first extraction electrode 13 has been deposited. As the film forming method, a sputtering method or a vacuum deposition method may be used. Examples of the sputtering method include a method of supplying all the constituent elements from a sputter target, and a selenization method of depositing Cu and Group IIIb elements by sputtering, and then performing a heating treatment in a H₂Se gas atmosphere. Furthermore, in the vacuum deposition method, a high quality light absorbing layer can be obtained by using a three-step method. The three-step method is a technique of initially vacuum depositing In and Ga, which are Group IIIb elements, and Se, which is a Group VIb element, subsequently depositing Cu, which is a Group Ib element, and Se, which is a Group Ib element, and finally depositing In, Ga and Se again.

[Process of Forming Buffer Layer on Light Absorbing Layer]

Buffer layers 15a and 15b are deposited on the light absorbing layer 14 thus obtained.

Examples of the method for forming the buffer layer 15a include vacuum processes such as a sputtering method, a vacuum deposition method and metal-organic chemical vapor deposition (MOCVD); and liquid processes such as a chemical bath deposition (CBD) method. In order to accurately control the composition of ZnO₁₋ₓSₓ that serves as the n-type buffer layer 15a, it is preferable to use vacuum processes such as a sputtering method, a vacuum deposition method and metal-organic chemical vapor deposition (MOCVD). For example, a high temperature process at a temperature such as 300° C. is not preferable because the buffer layer 15a of the embodiment may undergo separation into two phases. Thus, in the formation of the buffer layer 15a, the temperature of the substrate 11 at the time of film forming is preferably equal to or higher than room temperature and equal to or lower than 250° C.

In order to increase crystallinity, it is also effective to perform a heating treatment at a temperature in the range of equal to or higher than 50° C. and equal to or lower than 280° C., and more preferably equal to or higher than 100° C. and equal to or lower than 250° C., after the films are formed at a low temperature. When a heating treatment is carried out in this range, crystals of the buffer layer 15a grow, and the particle size can be adjusted to equal to or larger than 10 nm and equal to or smaller than 100 nm. Meanwhile, during this heating treatment, the same argon (Ar) gas atmosphere as that used during film formation is preferable.

Examples of the method for forming the buffer layer 15b include vacuum processes such as a sputtering method, a vacuum deposition method, and metal-organic chemical vapor deposition (MOCVD).

[Process of Forming Transparent Electrode on Buffer Layer]

Subsequently, a transparent electrode 16 is deposited on the buffer layer 15b.

Examples of the film forming method include vacuum processes such as a sputtering method, a vacuum deposition method, and metal-organic chemical vapor deposition (MOCVD).

[Process of Forming Extraction Electrode on Backside Electrode and Transparent Electrode]

A first extraction electrode 13 is deposited on a portion of the backside electrode 12 excluding at least the area where the light absorbing layer 14 has been formed.

A second extraction electrode 17 is deposited on a portion of the transparent electrode layer 16 excluding at least the area where the antireflective film 18 has been formed.

Examples of the film forming method include a sputtering method and a vacuum deposition method.

The formation of the first and second extraction electrodes 13, 17 may be carried out in one step, or may be respectively carried out as separate steps after any arbitrary steps.

[Process of Forming Antireflective Film on Transparent Electrode]

Finally, an antireflective film 18 is deposited on a portion of the transparent electrode 16 excluding at least the area where the second extraction electrode 17 has been formed.

Examples of the film forming method include a sputtering method and a vapor deposition method.

The photoelectric conversion element 10 or the thin film solar cell illustrated in the conceptual diagram of FIG. 1 is produced through the processes described above.

In the case of producing a compound thin film solar cell module, integration is made possible by inserting a step of segmenting the backside electrode using a laser, after the step of forming the backside electrode on the substrate, and by inserting a step of segmenting a sample by a mechanical scribe, respectively after the step of forming the buffer layer on the light absorbing layer and the step of forming the transparent electrode on the buffer layer.

Hereinafter, the present embodiment will be described in detail by way of Examples.

### Example 1A

A soda lime glass substrate is used as the substrate 11, and a Mo thin film that serves as a backside electrode 12 is deposited by a sputtering method to a thickness of about 700 nm. Sputtering is carried out by applying a power of 200 W at a radiofrequency (RF) in an Ar gas atmosphere, using a target of Mo.

After the Mo thin film that serves as the backside electrode 12 is deposited, a thin film of CuIn_{0.3}Ga_{0.7}Se₂ that serves as the light absorbing layer 14 is deposited to a thickness of about 2 μm. The film formation is carried out by a selenization method. First, an alloy film of CuIn_{0.3}Ga_{0.7} is deposited by a sputtering method, and thereafter, a heating treatment is carried out at 500° C. in a H₂Se atmosphere.

On the light absorbing layer 14 thus obtained, an n-type compound semiconductor of ZnO_{0.3}S_{0.7} is deposited to a thickness of about 100 nm as the buffer layer 15a at room temperature. The film formation is carried out by RF (high frequency) sputtering, but the process is carried out at an output power of 50 W in consideration of the plasma damage at the interface. Thereafter, a heating treatment is carried out at 150° C., and thus the crystal grain size becomes about 50 nm. On this buffer layer 15a, a ZnO thin film is deposited as the buffer layer 15b, and subsequently, ZnO:Al containing 2 wt % of alumina (Al₂O₃) is deposited to a thickness of about 1 μm as the transparent electrode 16. Al is deposited by a vapor deposition method as the extraction electrodes 13 and 17. The film thicknesses are set to 100 nm and 300 nm, respectively. Finally, MgF₂ is deposited as the antireflective film 18 by a sputtering method, and thereby the photoelectric conversion element of the embodiment can be obtained.

The crystal grain size of the photoelectric conversion element 10 thus obtained, the amount of S (x) of the buffer layer 15a and the amount of Ga (y) of the light absorbing layer 14, the crystal grain size, the conduction band offset (ΔE_{c} (eV)), the band gap of the buffer layer 15a (E_{gn} (eV)), the band gap of the light absorbing layer 14 (E_{gp} (eV)), the open circuit voltage (Voc), the short circuit current density (Jsc) and the peeling resistance of the photoelectric conversion element thus obtained were measured.

The electron state of from the buffer layer 15a to the light absorbing layer 14 can be evaluated by repeatedly subjecting the photoelectron conversion element to low energy ion etching that causes less irradiation damage, and to forward/inverse photoelectron spectroscopy. The band gaps (band gap of the buffer layer 15a (E_{gn} (eV)) and the band gap of the light absorbing layer 14 (E_{gp} (eV))) can be determined by estimating the VBM by ultraviolet photoelectron spectroscopy and the CBM by inverse photoelectron spectroscopy, and calculating the difference between the values. Furthermore, the changes in the electron state in the thickness direction that traverses the p-n junction can be evaluated from the repeated measurements described above, by plotting the VBM and the CBM against the etching time. The conductor offset ΔE_{c} (eV) can be estimated from the difference in the CBM between the light absorbing layer 14 and the buffer layer 15a.

Under irradiation of pseudo-sunlight at AM 1.5 by a solar simulator, the voltage was changed by using a voltage source and a multimeter, and thus the voltage at which the current became 0 mA under the irradiation of pseudo-sunlight was measured. Thus, the open circuit voltage (Voc) was obtained. The current at the time when no voltage was applied was measured, and thus the short circuit current density (Jsc) was obtained.

### Example 2A

A thin film solar cell is produced by the same method as in Example 1A, except that a thin film of CuIn_{0.5}Ga_{0.5}Se₂ is used as the light absorbing layer 14.

### Example 3A

A thin film solar cell is produced by the same method as in Example 1A, except that a thin film of CuIn_{0.7}Ga_{0.3}Se₂ is used as the light absorbing layer 14.

### Example 4A

A thin film solar cell is produced by the same method as in Example 1A, except that a thin film of CuInSe₂ is used as the light absorbing layer 14.

### Example 5A

A thin film solar cell is produced by the same method as in Example 1A, except that an n-type compound semiconductor layer of ZnO_{0.1}S_{0.9} is used as the buffer layer 15a.

### Example 6A

A thin film solar cell is produced by the same method as in Example 1A, except that a thin film of CuGaSe₂ is used as the light absorbing layer 14, and an n-type compound semiconductor layer of ZnS is used as the buffer layer 15a.

### Comparative Example 1A

A thin film solar cell is produced by the same method as in Example 1A, except that a thin film of CuInSe₂ is used as the light absorbing layer 14, and an n-type compound semiconductor layer of ZnO is used as the buffer layer 15a.

### Comparative Example 2A

A thin film solar cell is produced by the same method as in Example 1A, except that a thin film of CuIn_{0.7}Ga_{0.3}Se₂ is used as the light absorbing layer 14, and an n-type compound semiconductor layer of ZnO_{0.7}S_{0.3} is used as the buffer layer 15a.

### Comparative Example 3A

A thin film solar cell is produced by the same method as in Example 1A, except that a thin film of CuIn_{0.7}Ga_{0.3}Se₂ is used as the light absorbing layer 14, and an n-type compound semiconductor layer of ZnO_{0.5}S_{0.5} is used as the buffer layer 15a.

### Comparative Example 4A

A thin film solar cell is produced by the same method as in Example 1A, except that a thin film of CuIn_{0.5}Ga_{0.5}Se₂ is used as the light absorbing layer 14, and an n-type compound semiconductor layer of ZnO_{0.5}S_{0.5} is used as the buffer layer 15a.

### (Comparative Example 1B) to (Comparative Example 6B)

A compound thin film solar cell is produced by the same method as that used in Example 1A to Example 6A, except that a heating treatment after film formation is not carried out during the process of forming the buffer layer 15a. The crystal grain size becomes about 5 nm.

### (Comparative Example 1C) to (Comparative Example 6C)

A compound thin film solar cell is produced by the same method as that used in Example 1A to Example 6A, except that a heating treatment is carried out at 300° C. after film formation during the process of forming the buffer layer 15a. The crystal grain size becomes about 150 nm.

A comparison of performance of the compound thin film solar cells obtained in Examples 1A to 6A, Comparative Examples 1A to 4A, Comparative Examples 1B to 6B, and Comparative Examples 1C to 6C is presented in Table 1 and Table 2.

TABLE 1

| | | | Crystal | | | |
|---|---|---|---|---|---|---|
| | | | grain size of | | | |
| Example | x | y | n layer (nm) | ΔE_{c} (eV) | E_{gn} (eV) | E_{gp} (eV) |
| Example 1A | 0.7 | 0.7 | 50 | 0 | 3.1 | 1.43 |
| Example 2A | 0.7 | 0.5 | 50 | 0.14 | 3.1 | 1.28 |
| Example 3A | 0.7 | 0.3 | 70 | 0.27 | 3.1 | 1.16 |
| Example 4A | 0.7 | 0.0 | 100 | 0.4 | 3.1 | 1.01 |
| Example 5A | 0.9 | 0.7 | 50 | 0.4 | 3.5 | 1.43 |
| Example 6A | 1.0 | 1.0 | 40 | 0.35 | 3.8 | 1.68 |
| Comparative | 0.0 | 0.0 | 50 | −0.28 | 3.6 | 1.01 |
| Example 1A | | | | | | |
| Comparative | 0.3 | 0.3 | 50 | −0.43 | 3 | 1.16 |
| Example 2A | | | | | | |
| Comparative | 0.5 | 0.3 | 50 | −0.43 | 2.8 | 1.16 |
| Example 3A | | | | | | |
| Comparative | 0.5 | 0.5 | 50 | −0.55 | 2.8 | 1.28 |
| Example 4A | | | | | | |
| Comparative | 0.7 | 0.7 | 5 | 0 | 3.1 | 1.43 |
| Example 1B | | | | | | |
| Comparative | 0.7 | 0.5 | 5 | 0.14 | 3.1 | 1.28 |
| Example 2B | | | | | | |
| Comparative | 0.7 | 0.3 | 5 | 0.27 | 3.1 | 1.16 |
| Example 3B | | | | | | |
| Comparative | 0.7 | 0.0 | 5 | 0.4 | 3.1 | 1.01 |
| Example 4B | | | | | | |
| Comparative | 0.9 | 0.7 | 5 | 0.4 | 3.5 | 1.43 |
| Example 5B | | | | | | |
| Comparative | 1.0 | 1.0 | 5 | 0.35 | 3.8 | 1.68 |
| Example 6B | | | | | | |
| Comparative | 0.7 | 0.7 | 150 | 0 | 3.1 | 1.43 |
| Example 1C | | | | | | |
| Comparative | 0.7 | 0.5 | 150 | 0.14 | 3.1 | 1.28 |
| Example 2C | | | | | | |
| Comparative | 0.7 | 0.3 | 150 | 0.27 | 3.1 | 1.16 |
| Example 3C | | | | | | |
| Comparative | 0.7 | 0.0 | 150 | 0.4 | 3.1 | 1.01 |
| Example 4C | | | | | | |
| Comparative | 0.9 | 0.7 | 150 | 0.4 | 3.5 | 1.43 |
| Example 5C | | | | | | |
| Comparative | 1.0 | 1.0 | 150 | 0.35 | 3.8 | 1.68 |
| Example 6C | | | | | | |

TABLE 2

| | | | | Peeling |
|---|---|---|---|---|
| Example | Voc | Jsc | η | resistance |
| Example 1A | B | A | B | A |
| Example 2A | A | B | B | A |
| Example 3A | A | B | B | A |
| Example 4A | A | C | B | A |
| Example 5A | A | A | A | A |
| Example 6A | A | B | B | A |
| Comparative | D | C | D | A |
| Example 1A | | | | |
| Comparative | D | B | D | A |
| Example 2A | | | | |
| Comparative | D | B | D | A |
| Example 3A | | | | |
| Comparative | D | B | D | A |
| Example 4A | | | | |
| Comparative | B | C | C | B |
| Example 1B | | | | |
| Comparative | A | C | C | B |
| Example 2B | | | | |
| Comparative | A | C | C | B |
| Example 3B | | | | |
| Comparative | A | D | D | B |
| Example 4B | | | | |
| Comparative | A | C | C | B |
| Example 5B | | | | |
| Comparative | A | C | C | B |
| Example 6B | | | | |
| Comparative | B | C | C | D |
| Example 1C | | | | |
| Comparative | A | C | C | D |
| Example 2C | | | | |
| Comparative | A | C | C | D |
| Example 3C | | | | |
| Comparative | A | D | D | D |
| Example 4C | | | | |
| Comparative | A | C | C | D |
| Example 5C | | | | |
| Comparative | A | C | C | D |
| Example 6C | | | | |

A: Very Good,
B: Good,
C: Mediocre,
D: Bad
η = Voc · Jsc · FF/P · 100

As discussed in the above, ΔE_{c} is preferably equal to or greater than 0 eV and equal to or less than +0.4 eV, and this range is effective for the performance of the open circuit voltage Voc. Furthermore, a larger band gap of the n-type buffer layer (E_{gn}) is more preferred because the absorption of light having shorter wavelengths can be suppressed at the buffer layer. In addition, the band gap of the light absorbing layer (E_{gp}) is preferably closer to 1.4 eV. The size of this band gap is effective in the performance of the short circuit current density Jsc. The crystal grain size of the n-type buffer layer also affects the performance of the short circuit current density Jsc. When the crystal grain size is 5 nm, the short circuit current density Jsc is decreased by a decrease in the carrier mobility, and when the crystal grain size is 150 nm, the short circuit current density Jsc is decreased by the generation of a shunt path or the like. The conversion efficiency is deteriorated. A comparison of performance of the conversion efficiency η can be made from the Voc and the Jsc. The crystal grain size of the n-type buffer layer also affects the peeling resistance at the p-n junction interface, so that when the crystal grain size is 150 nm, peeling resistance decreases as a result of void formation.

When the photoelectric conversion element of the present invention is used in solar cells, a solar cell having high conversion efficiency can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion element comprising a light absorbing layer containing copper (Cu), at least one Group IIIb element selected from the group including aluminum (Al), indium (In) and gallium (Ga), and sulfur (S) or selenium (Se), and having a chalcopyrite structure; and a buffer layer formed from zinc (Zn) and oxygen (O) or sulfur (S), wherein the molar ratio represented by S/(S+O) of the buffer layer is equal to or greater than 0.7 and equal to or less than 1.0, and the crystal grain size is equal to or greater than 10 nm and equal to or less than 100 nm.

2. The element according to claim 1, wherein the molar ratio of Ga/Group IIIb elements of the light absorbing layer is equal to or greater than 0.5 and equal to or less than 1.0.

3. The element according to claim 1, wherein the difference in the conduction band minimum of the light absorbing layer and the conduction band minimum of the buffer layer is equal to or greater than 0 and equal to or less than 0.4.

4. The element according to claim 1, wherein the buffer layer is formed in a single phase.

5. The element according to claim 1, wherein the element ratio of Ga/(Ga+In) of the light absorbing layer is equal to or greater than 0.5 and equal to or less than 1.0.

6. The element according to claim 1, wherein the element ratio of Ga/(Ga+In) of the light absorbing layer is equal to or greater than 0.6 and equal to or less than 0.9.

7. The element according to claim 1, wherein the element ratio of Ga/(Ga+In) of the light absorbing layer is equal to or greater than 0.65 and equal to or less than 0.85.

8. The element according to claim 1, wherein the light absorbing layer is formed from CuIn_{1-y}Ga_{y}Se₂, and y is equal to or greater than 0 and equal to or less than 1.

9. The element according to claim 1, wherein the light absorbing layer is formed from any one of Cu(In,Ga)Se₂, Cu(In,Ga)₃Se₅, and Cu(Al,Ga,In)Se₂.

10. A solar cell comprising a light absorbing layer containing copper (Cu), at least one Group IIIb element selected from the group including aluminum (Al), indium (In) and gallium (Ga), and sulfur (S) or selenium (Se), and having a chalcopyrite structure; and a buffer layer formed from zinc (Zn) and oxygen (O) or sulfur (S), wherein the molar ratio represented by S/(S+O) of the buffer layer is equal to or greater than 0.7 and equal to or less than 1.0, and the crystal grain size is equal to or greater than 10 nm and equal to or less than 100 nm.

11. The cell according to claim 10, wherein the molar ratio of Ga/Group IIIb elements of the light absorbing layer is equal to or greater than 0.5 and equal to or less than 1.0.

12. The cell according to claim 10, wherein the difference in the conduction band minimum of the light absorbing layer and the conduction band minimum of the buffer layer is equal to or greater than 0 and equal to or less than 0.4.

13. The cell according to claim 10, wherein the buffer layer is formed in a single phase.

14. The cell according to claim 10, wherein the element ratio of Ga/(Ga+In) of the light absorbing layer is equal to or greater than 0.5 and equal to or less than 1.0.

15. The cell according to claim 10, wherein the element ratio of Ga/(Ga+In) of the light absorbing layer is equal to or greater than 0.6 and equal to or less than 0.9.

16. The cell according to claim 10, wherein the element ratio of Ga/(Ga+In) of the light absorbing layer is equal to or greater than 0.65 and equal to or less than 0.85.

17. The cell according to claim 10, wherein the light absorbing layer is formed from CuIn_{1-y}Ga_{y}Se₂, and y is equal to or greater than 0 and equal to or less than 1.

18. The cell according to claim 10, wherein the light absorbing layer is formed from any one of Cu(In,Ga)Se₂, Cu(In,Ga)₃Se₅, and Cu(Al,Ga,In)Se₂.
